(19) United States
(12) Patent Application Publication
(10) Pub. No.: US 2017/0236676 A1
(43) Pub. Date: Aug. 17, 2017

(54) CIRCUIT BREAKER

(71) Applicant: EATON INDUSTRIES (AUSTRIA) GMBH, Schrems (AT)

(72) Inventor: Michael BARTONEK, Vienna (AT)

(21) Appl. No.: 15/319,814

(22) PCT Filed: Jun. 19, 2015
(86) PCT No.: PCT/EP2015/063795

§ 371 Date: Apr. 3, 2017

(30) Foreign Application Priority Data
Jun. 20, 2014 (DE) 10 2014 108 657.0

(51) Int. Cl. H01H 89/06; H02H 9/00; H02H 1/00; H02H 7/22; H03K 17/567; H02J 13/00

(52) U.S. Cl. CPC H01H 89/06; H03K 17/567; H02J 13/0075; H02H 1/0023; H02H 1/0061; H02H 7/22; H02H 9/001

(57) ABSTRACT

A circuit breaker with a switching path has at least one line interruption apparatus, wherein the circuit breaker has a disconnection unit and a connection unit which are each connected to the line interruption apparatus. The switching device has at least one measuring arrangement for measuring at least one electrical variable on the at least one switching path. The disconnection unit further has a comparison and decision unit, which comparison and decision unit is connected to the measuring arrangement and to the line interruption apparatus. The circuit breaker has a first data interface, which first data interface is designed to receive at least one connection command and/or one disconnection command, and wherein the first data interface is connected to the disconnection unit and the connection unit.

### CROSS-REFERENCE TO RELATED APPLICATIONS

This application is a U.S. national stage application under 35 U.S.C. §371 of International Application No. PCT/EP2015/063795, filed on Jun. 19, 2015, and claims benefit to German Patent Application No. DE 10 2014 108 657.0, filed on Jun. 20, 2014. The International Application was published in German on Dec. 23, 2015, as WO 2015/193468 A1 under PCT Article 21(2).

### FIELD

The invention relates to a circuit breaker.

### BACKGROUND

It is a known procedure, and prescribed by law in most countries, to protect electric power systems or subsystems by means of circuit breakers. These circuit breakers are hardly ever switched during regular operation of the electric power system in question. Electrical consumers within an electric power system are normally started up by means of another switching device arranged between the circuit breaker and the consumer. A drawback of such an approach is that there are two switching devices arranged in series.

Moreover, there is a clear trend towards automated or remote-controlled execution of switching operations. Such approaches, however, usually entail the drawback of greater complexity and they can hardly be modified, especially expanded, at a later point in time.

Furthermore, there are ongoing efforts aimed at better utilizing the electric power systems, whereby so-called intelligent load management is provided in order to reduce load peaks in individual subsystems.

### SUMMARY

An aspect of the invention provides a circuit breaker, comprising: a breaker gap including a line interruption device, arranged in the breaker gap; a switch-off unit, connected to the line interruption device, the switch-off unit being configured (to open the at least one breaker gap in a prescribed manner. A switch-on unit, connected to the line interruption device, the switch-on unit being configured to close the at least one breaker gap in a prescribed manner; a measuring arrangement, configured to measure at least one electrical quantity at the breaker gap; and a first data interface, configured to receive at least one switch-on command and/or one switch-off command. The first data interface is connected to the switch-off unit and to the switch-on unit. The switch-off unit includes a comparison and decision unit connected to the measuring arrangement and to the line interruption device.

### BRIEF DESCRIPTION OF THE DRAWINGS

The present invention will be described in even greater detail below based on the exemplary figures. The invention is not limited to the exemplary embodiments. All features described and/or illustrated herein can be used alone or combined in different combinations in embodiments of the invention. The features and advantages of various embodiments of the present invention will become apparent by reading the following detailed description with reference to the attached drawings which illustrate the following:

FIG. 1 a block diagram of an exemplary embodiment of an installation arrangement according to the invention;

FIG. 2 a block diagram of a first embodiment of a switching device according to the invention;

FIG. 3 a block diagram of a second embodiment of a switching device according to the invention; and

FIG. 4 a block diagram of a third embodiment of a switching device according to the invention.

### DETAILED DESCRIPTION

Before this backdrop set forth in the Background, an aspect of the invention provides a circuit breaker of the above-mentioned type with which the cited drawbacks can be avoided and with which the structure of an installation arrangement can be simplified, and also so that its safety can be increased.

As a result, switching tasks for the usual operation or regular start-up and shutdown of electrical consumers can be carried out without additional switching devices. This means that the structure of an electrical installation arrangement can be simplified. Consequently, the flexibility within an electrical installation arrangement can be increased. Therefore, a circuit breaker can also be employed for the normally provided switching operations in an electrical installation, whereby the circuit breaker in question can be controlled remotely. This means that it is possible to save on the number of switching devices in an electrical installation arrangement, whereby, through the use of a circuit breaker for the regular operational switching operations, the safety in the entire installation arrangement can be improved. Special advantages arise from the use of such circuit breakers in conjunction with a so-called smart meter. This also allows for a better load management in terms of the capability to switch off individual branches of a consumer.

Before this backdrop, it is an aspect of the invention provides a method of the above-mentioned type with which the drawbacks cited above can be avoided and with which the structure of an installation arrangement can be simplified, and also so that its safety can be increased and the load management can be simplified.

In this manner, the advantageous effects presented above can be attained.

Express reference is hereby being made to the wording of the patent claims, as a result of which the claims are included here in the description by reference and are considered to be literally cited.

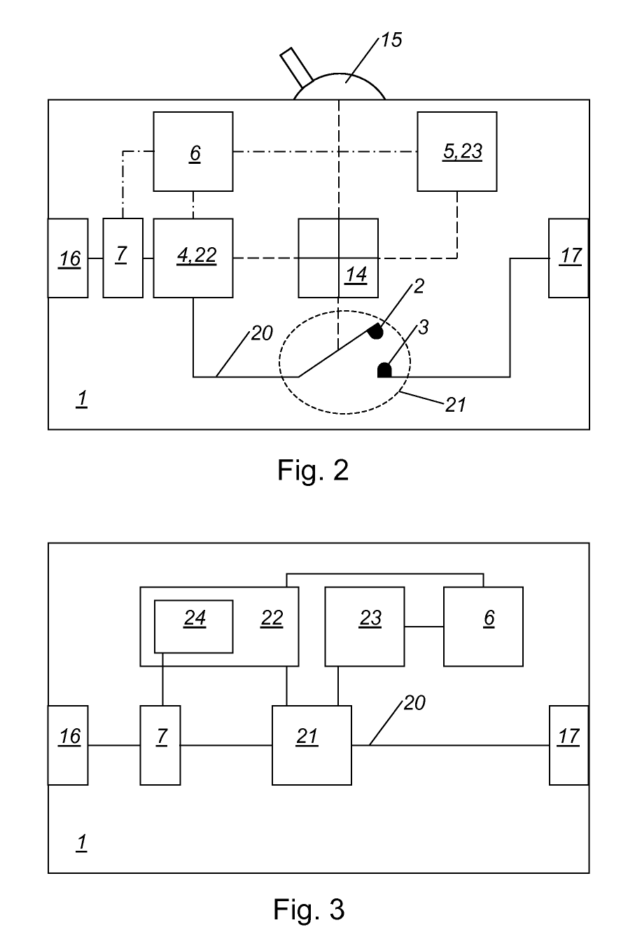

FIGS. 2, 3 and 4 each show an embodiment of a circuit breaker 1 having at least one breaker gap 20, whereby at least one line interruption device 21 is arranged in the breaker gap 20, whereby the circuit breaker 1 has a switch-off unit 22 that is connected to the line interruption device 21 that serves to open the at least one breaker gap 20 in a prescribed manner, whereby the circuit breaker 1 has a switch-on unit 23 that is connected to the line interruption device 21 that serves to close the at least one breaker gap 20 in a prescribed manner, whereby the circuit breaker 1 has at least one measuring arrangement 7 to measure at least one electrical quantity at the at least one breaker gap 20, whereby the switch-off unit 22 also has a comparison and decision unit 24 that is connected to the measuring arrangement 7 as well as to the line interruption device 21, whereby the circuit breaker 1 has a first data interface 6 that is configured to receive at least one switch-on command and/or one switch-off command, and whereby the first data interface 6 is connected to the switch-off unit 22 and to the switch-on unit 23.

As a consequence, switching tasks for the operational and regular start-up and shutdown of electrical consumers 10 can be carried out without additional switching devices. This means that the structure of an electrical installation arrangement 8 can be simplified. Consequently, the flexibility within an electrical installation arrangement 8 can be increased. Therefore, a circuit breaker 1 can also be employed for the normally provided switching operations in an electrical installation, whereby the circuit breaker 1 in question can be controlled remotely. This means that it is possible to save on the number of switching devices in an electrical installation arrangement 8, whereby, through the use of a circuit breaker 1 for the operational switching operations, the safety in the entire installation arrangement 8 can be improved. Special advantages arise from the use of such circuit breakers 1 in conjunction with a so-called smart meter. This also allows for a better load management in terms of the capability to switch off individual branches of a consumer.

The circuit breaker 1 can be configured as any kind of circuit breaker 1, thus as a switching device that is configured to monitor physical, especially electrical, states in a section of an electric power system 9 so that the appertaining part of the power system 9 can be switched off if certain limit values are exceeded. Preferably, it is provided for the circuit breaker 1 to be configured as a line circuit breaker and/or as a power breaker.

The circuit breaker 1 has at least one breaker gap 20, whereby it is especially provided for the circuit breaker 1 to have two breaker gaps 20, a first breaker gap for a phase and a second breaker gap for a neutral conductor of an electric power system 9.

The circuit breaker 1 also has a line interruption device 21 that is arranged in the at least one breaker gap 20, whereby it is especially provided for a line interruption device 21 to be arranged in each breaker gap 20. Two different embodiments of a circuit breaker 1 which differ particularly in terms of the configuration of the line interruption device 21 will be described below.

FIG. 2 shows a first embodiment of a switching device according to the invention, whereby the line interruption device 21 is configured in the form of conventional switching contacts 2, 3. It should be pointed out that it is preferably provided for the switching contacts 2, 3 in question to be configured so as to meet the requirements of the greater number of switching cycles in comparison to a pure circuit breaker 1, in other words, approximately like a contactor for the envisaged electrical performance class.

The circuit breaker 1 according to FIG. 2 has at least a first switching contact 2 and a second switching contact 3, whereby at least one of the two switching contacts 2, 3 is configured as a moving switching contact. In the symbolic depiction shown in FIG. 2, the first switching contact 2 is configured as a moving switching contact. Preferably, the circuit breaker 1 has a breaker latching mechanism 14 that controls the movement of the moving switching contact 2.

Therefore, in the closed position of the switching contacts 2, 3, that is to say, in a position in which the switching contacts 2, 3 are in contact with each other, they form part of a conductive current path or part of a breaker gap 20 through the circuit breaker 1, running from a first connection terminal 16 to a second connection terminal 17 of the circuit breaker 1.

The circuit breaker 1 has at least one switch-off unit 22 in the form of a trip element 4 that serves to open the switching contacts 2, 3 in a prescribed manner. When the circuit breaker 1 is configured as a line circuit breaker, it is provided for the circuit breaker 1 to have two trip elements, an electromagnetic short-circuit trip element as well as an electro-thermal excess-voltage 4. Such trip elements are generally known. In FIG. 2, only one trip element 4 is shown in the drawing. The at least one trip element 4 acts on the preferably provided breaker latching mechanism 14.

Moreover, the circuit breaker 1 has a switch-on unit 23 configured as a switch-on device 5, for closing the switching contacts 2, 3 in a prescribed manner. In the preferred embodiment, the switch-on device 5, which is configured along the lines of an electromagnetic device, is operationally connected to the breaker latching mechanism 14 for purposes of closing the switching contacts 2, 3.

Furthermore, the circuit breaker 1 has a hand-leg element 15 that preferably likewise acts on the breaker latching mechanism 14.

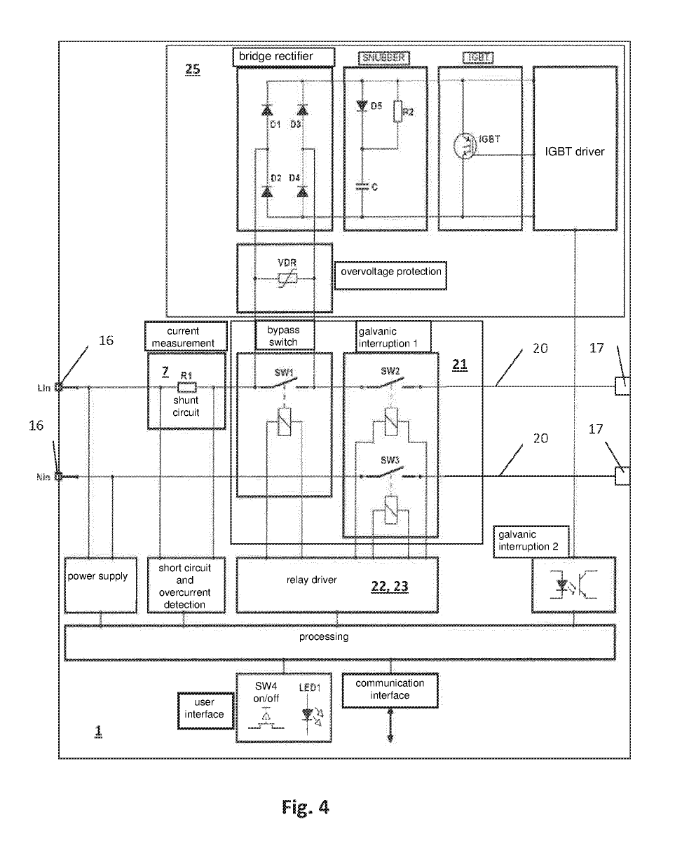

FIG. 3 shows a block diagram of a second and particularly preferred embodiment of a circuit breaker 1 according to the present invention. In this embodiment, the line interruption device 21 is especially configured so as to comprise a semiconductor interrupter arrangement 25 for each breaker gap 20, preferably encompassing at least one IGBT. Preferably, it is provided for the switching device to also have switching contacts 2, 3 for galvanically interrupting the at least one breaker gap 20. The semiconductor interrupter arrangement 25 as well as the switching contacts 2, 3 are not shown in FIG. 3 but in FIG. 4. Circuit breakers 1 configured in this manner are also referred to as hybrid switching devices.

FIG. 4 shows an expanded and detailed block diagram of such a circuit breaker 1. Since the line interruption device 21 is configured so as to comprise a semiconductor interrupter arrangement 25, many switching cycles can be carried out without any perceptible signs of wear and tear. Such a circuit breaker 1 can also be easily controlled remotely.

In a circuit breaker 1 according to FIGS. 3 and 4, the switch-off unit 22 controls the relay driver depicted in FIG. 4 as well as the switch-on unit 23.

The circuit breaker 1 also has a measuring arrangement 7 to measure at least one electrical quantity at the at least one breaker gap 20, whereby it is especially provided for the measuring arrangement 7 to be configured at least to measure a current flow in the at least one breaker gap 20. The circuit breaker 1 according to FIG. 4 accordingly has a shunt R1.

It is especially preferable for the measuring arrangement 7 to also be configured to measure an electric power picked up via the circuit breaker 1, especially an apparent power and/or an effective power. A measurement of the effective power is only possible with embodiments of the circuit breaker 1 which have a multi-polar configuration and through which an external conductor and a neutral conductor pass.

In this context, when it comes to circuit breakers 1 that only switch one phase and consequently cannot ascertain either the voltage of the electric power system or the phase angle between voltage and current, it can also be considered sufficient to detect only the current flowing via the circuit breaker 1 from which, on the basis of the approximate system voltage, conclusions can then be drawn about the apparent power and thus about the load. If the type of consumer to be switched or else its cos φ is known, conclusions can also be drawn about the effective power on the basis of the measured current.

The measuring arrangement 7 is connected to a comparison and decision unit 24 which is part of the switch-off unit 22. The comparison and decision unit 24 is also connected to the line interruption device 21. Recorded measured values are compared in the comparison and decision unit 24 to at least one limit value so that, if the value has exceeded or fallen below the limit value, the line interruption device 21 can be actuated and the breaker gap 20 is opened.

It is especially provided for the measuring arrangement 7 to be configured to detect an edge steepness of the detected electrical quantity. This allows a very early detection of any excessive rise in an electrical quantity, especially in a current, so that the appertaining breaker gap 20 can already be opened before a critical state occurs.

It should be pointed out that it is preferably provided for a conventionally configured trip element 4 of a circuit breaker 1, for instance, according to FIG. 2, to be considered as a combination of a measuring arrangement 7 with a comparison and decision unit 24 insofar as a momentary current value is compared to a limit value to the effect that tripping takes place in the form of a mechanical change in the appertaining trip element 4 at a certain current value.

The circuit breaker 1 also has a first data interface 6 that serves to receive at least one switch-on command and/or one switch-off command. The first data interface 6 is connected to at least the switch-off unit 22 and the switch-on unit 23, or to the trip element 4 and the switch-on device 5. In this context, in response to such a switch-on command, it is provided for the breaker gap 20 to be closed, starting from an interrupted state, and, in response to a switch-off command, for a conductive breaker gap 20 to be opened or interrupted, each time with the participation of the line interruption device 21.

Preferably, the first data interface 6 is configured as a bidirectional radio interface, as a result of which there is no need to lay additional lines, thereby minimizing the resources needed to create an installation arrangement 8 according to the invention while achieving a high degree of flexibility.

For purposes of systematically actuating the circuit breaker 1, it is preferably provided for the first data interface 6 to have a first unique identifier or UID, that is to say, an unambiguous device identification.

Particularly in the case of the arrangement of a plurality of circuit breakers 1 according to the invention that can be augmented by additional components inside a switching cabinet, the combination of a dedicated UID and the configuration of the first data interface 6 as a radio interface serve to positively support the structuring of an “intelligent” electrical installation arrangement 8 since it is possible to dispense with a separate hardwired incorporation of the individual circuit breakers 1 into the installation arrangement 8.

Preferably, it is provided for the measuring arrangement 7 to be connected to the first data interface 6 so as to relay the ascertained measured results. In particular, so as to convey these measured results to a smart grid and thus allow better control of the power system.

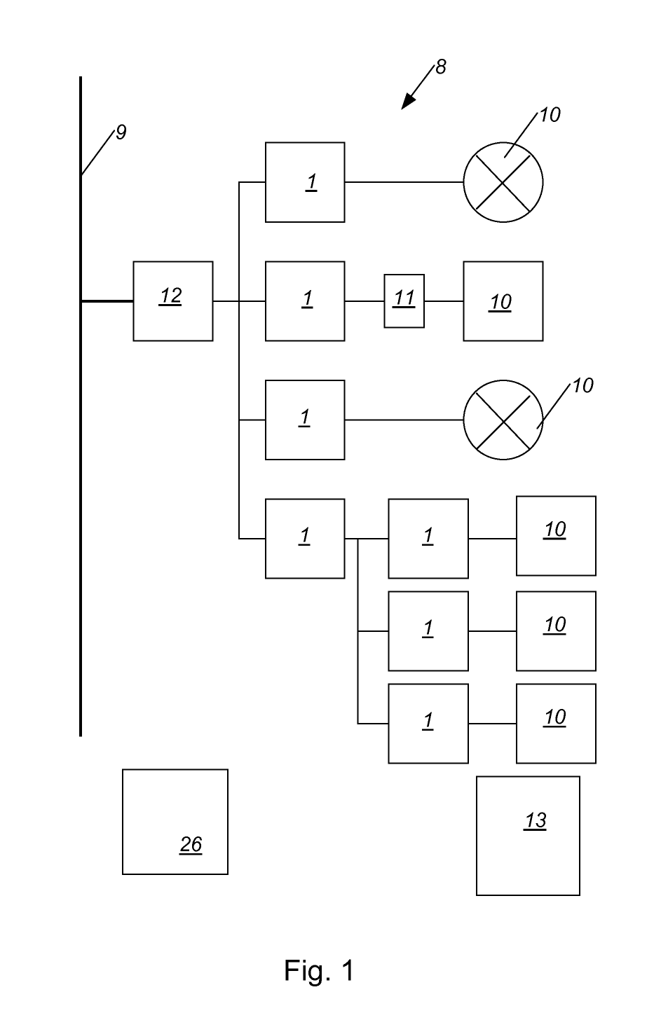

By way of an example, FIG. 1 shows an embodiment of an electrical installation arrangement 8 comprising at least one circuit breaker 1 according to the invention. The electrical installation arrangement 8 can also be referred to as an energy-distribution and/or electrical safety system. This arrangement is connected to an electric power system 9, hence an energy-distribution system, especially a low-voltage supply system, said power system 9 preferably connecting a power plant or a transformer substation to a final customer. In this context, it can also be provided for the so-called final customer itself to be, for example, a power producer via a photovoltaic installation, and to itself generate electric power and to feed it into the electric power system 9.

The installation arrangement 8 according to the invention here is part of a structure and/or of the terrain of a final buyer of electric energy or of a small supplier of electric energy. In this manner, the installation arrangement 8 can also comprise decentralized sources of energy such as, for example, a solar power system. The electric power system 9, like the other electric connections in FIG. 1, is only depicted with a single line, whereby, however, preferably a plurality of electric conductors are provided.

The circuit breaker 1 is at least indirectly connected to an electric power system 9, whereby, between the circuit breaker 1 and the power system 9, there is an electricity meter associated with an energy buyer and/or an energy supplier. It is preferably provided for such an electricity meter to be configured as an intelligent electricity meter 12. Such intelligent electricity meters 12 are also referred to as smart meters.

It is preferably provided for the intelligent electricity meter 12 to have a third data interface with a third unique identifier. It should be pointed out in this context that the data interfaces of the various devices are preferably configured so as to be wireless, and also so as to be identically configured in terms of the transmission protocol used in order to allow communication among the devices.

In particular, it is provided for the data transmission among the individual devices and/or for the control of the individual devices to be carried out by means of a SCADA system or to be integrated into a SCADA system. SACDA stands for supervisory control and data acquisition.

At least one electrical consumer 10 is connected to the at least one circuit breaker 1. Here, it is preferably provided for only the circuit breaker 1 to be arranged in a feed line leading to the electrical consumer 10. As depicted in FIG. 1, there can be a further division into several branches downstream from a circuit breaker 1, whereby each branch containing another circuit breaker 1 according to the invention, and at least one electrical consumer 10, is connected downstream from each circuit breaker 1.

Therefore, the electric connection of the circuit breaker 1 to the consumer 10 is free of any conventional switching devices whose purpose is to switch the consumer 10 on or off. It is provided for only the circuit breaker 1 or, in case of an arrangement of several such circuit breakers 1, one of the circuit breakers 1, to be provided to operationally switch the electrical consumer 10 on or off. Consequently, only at least one circuit breaker 1 is arranged between the power system 9 and the electrical consumer 10 as a switching device. Even though additional components such as, for instance, an electricity meter or a sensor device 11, can be arranged between the power system 9 and the electrical consumer 10, they do not switch the consumer 10, something which only takes place when one of the circuit breakers 1 is appropriately switched.

FIG. 1 shows an electrical installation arrangement 8 with seven circuit breakers 1. An electrical consumer 10 is connected to three of the circuit breakers 1. Two of the consumers are configured here as lights. Of course, it can be provided for several consumers 10 to be switched by means of one circuit breaker 1.

As already elaborated upon, additional circuit breakers are arranged in parallel downstream from one of the circuit breakers 1. This arrangement permits a more refined selective switching of individual consumers 10, whereby one single circuit breaker 1 can simultaneously switch on or off all of the consumers 10 that are connected downstream from the appertaining circuit breaker 1. Due to the additional division downstream from a circuit breaker 1 and the safeguarding of the individual branches likewise by means of the circuit breakers 1 according to the invention, additional selectivity can be achieved since all of the circuit breakers 1 have a first data interface 6 and these can also be individually or selectively actuated and switched.

Preferably, as shown in FIG. 1, the electrical installation arrangement 8 has at least one regulation and/or control unit 13. The regulation and/or control unit 13 has a fourth data interface for communication with the at least one circuit breaker 1 and/or with the at least one sensor device 11 and/or with the intelligent electricity meter 12. The regulation and/or control unit 13 serves to enter and transmit switching commands to the circuit breaker 1, whereby it can be provided for several regulation and/or control units 13 to be present, and also for a regulation and/or control unit 13 to be configured together with the intelligent electricity meter 12 that is preferably provided.

It is preferably provided for the electrical installation arrangement 8 to also have at least one sensor device 11 for detecting at least one non-electrical quantity, especially a temperature. Such sensor devices 11 can be arranged physically directly on components, also, for instance, lines of the electrical installation arrangement 8, or else at other places in the area of the electrical installation arrangement 8. The further switching behavior of the electrical installation arrangement 8 can be influenced by detecting a temperature, a lighting state or, if applicable, a fire.

The sensor device 11 preferably has a second data interface with a second unique identifier, as a result of which the ascertained measured data can be transmitted to the regulation and/or control unit 13.

Moreover, the electrical installation arrangement 8 preferably has a master unit 26 that comprises a fifth data interface with a fifth unique identifier, said fifth data interface being at least configured for communication with the at least one regulation and/or control unit 13. In this context, it can preferably be provided for the communication between the master unit 26 and the regulation and/or control unit 13 to take place via cables.

Owing to the inventive architecture of an electrical installation arrangement 8, a good overview of the processes inside the installation in question can be obtained at a centralized or decentralized place, especially also about the status of the installation as well as of the individual branches.

Thanks to this good overview of the electrical installation arrangement 8, a systematic switching off of individual circuit breakers can have a balancing effect on the power system load.

It is preferably provided for a priority level to be assigned to the individual circuit breakers. In this manner, a higher priority level can be assigned, for example, to a circuit breaker to which a safety-critical consumer is connected, as a result of which this circuit breaker is not switched off, thereby reducing the power system load. Circuit breakers 1 which are only connected upstream from unimportant consumers, in contrast, can be switched off by the master unit 26 if the power system load makes this necessary. This makes it possible to dispense with switching off entire subsystems or entire consumers downstream from an intelligent electricity meter.

For the operation of an electrical consumer 10 that is connected to an electric power system 9 via a circuit breaker 1, in order to start up the electrical consumer 10, it is provided for a switch-on command to be transmitted by a regulation and/or control unit 13 to the circuit breaker 1 via the data interfaces 6 of the individual devices. Subsequently, in response to the received switch-on command, in the configuration of the circuit breaker according to FIG. 2, the switching contacts 2,3 of the circuit breaker 1 are closed by the switch-on device 5 of the circuit breaker 1, and in this manner, the electrical consumer 10 is put into operation.

In order to shut down the electrical consumer 10, a switch-off command is transmitted by the regulation and/or control unit 13 to the circuit breaker 1 via the data interfaces 6 of the individual devices. Subsequently, the trip element 4 of the circuit breaker 1 causes the switching contacts 2,3 of the circuit breaker 1 to open, and in this manner, the electrical consumer 10 is shut down.

In the configuration of the circuit breaker according to FIG. 3, it is provided for the electric breaker gap 20 of the circuit breaker 1 to be closed by the switch-on unit 23 of the circuit breaker 1, whereby, in order to shut down the electrical consumer 120, a switch-off command is transmitted by the regulation and/or control unit 13 to the circuit breaker 1 via the data interfaces 6, as a result of which the electric breaker gap 20 of the circuit breaker 1 is subsequently opened by the switch-off unit 22 of the circuit breaker 1, and in this manner, the electrical consumer 10 is shut down.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B, and C” should be interpreted as one or more of a group of elements consisting of A, B, and C, and should not be interpreted as requiring at least one of each of the listed elements A, B, and C, regardless of whether A, B, and C are related as categories or otherwise. Moreover, the recitation of “A, B, and/or C” or “at least one of A, B, or C” should be interpreted as including any singular entity from the listed elements, e.g., A, any subset from the listed elements, e.g., A and B, or the entire list of elements A, B, and C.

1. A circuit breaker, comprising:
a breaker gap including a line interruption device, arranged in the breaker gap;
a switch off unit, connected to the line interruption device, the switch-off unit being configured to open the at least one breaker gap in a prescribed manner;
a switch-on unit, connected to the line interruption device, the switch-on unit being configured to close the at least one breaker gap in a prescribed manner;
a measuring arrangement, configured to measure at least one electrical quantity at the one breaker gap; and
a first data interface, configured to receive at least one switch-on command and/or one switch-off command,
wherein the first data interface is connected to the switch-off unit and to the switch-on unit, and
wherein the switch-off unit including a comparison and decision unit connected to the measuring arrangement and to the line interruption device.

2. The circuit breaker of claim 1, wherein the line interruption device is configured to include a semiconductor interrupter arrangement.

3. The circuit breaker of claim 1, wherein the line interruption device includes a switching contact configured to galvanically interrupt the breaker gap.

4. The circuit breaker of claim 1, wherein the measuring arrangement is configured to measure a current flow in the breaker gap and/or to measure an electric power picked up via the circuit breaker.

5. The circuit breaker of claim 1, herein the measuring arrangement is configured to detect an edge steepness of the detected electrical quantity.

6. The circuit breaker of claim 1, wherein the measuring arrangement is connected to the first data interface.

7. The circuit breaker of claim 1, wherein the first data interface is configured as a bidirectional radio interface.

8. The circuit breaker of claim 1, wherein the first data interface includes a first unique identifier.

9. An electrical installation arrangement, comprising:
the circuit breaker of claim 1,
wherein the circuit breaker is at least indirectly connected to an electric power system, and
wherein an electrical consumer and/or producer is connected to the circuit breaker.

10. The arrangement of claim 9, wherein the circuit breaker is arranged in a feed line leading to the electrical consumer and/or to the producer, and
wherein the circuit breaker is configured to switch the electrical consumer on and off during regular operation.

11. The arrangement of claim 9, further comprising:
a sensor device configured to detect at least one non-electrical quantity,
wherein the sensor device includes a second data interface including a second unique identifier.

12. The arrangement of claim 9, further comprising:
an intelligent electricity meter,
wherein the intelligent electricity meter includes a third data interface including a third unique identifier.

13. The arrangement of claim 9, further comprising:
a regulation and/or control unit including a fourth data interface including a fourth unique identifier which is configured to communicate with the circuit breaker and/or with a sensor device and/or with an intelligent electricity meter.

14. The arrangement of claim 13, further comprising: a master unit including a fifth data interface including a fifth unique identifier which is configured to communicate with the regulation and/or control unit.

15. The arrangement of claim 9, wherein the first data interface, second data interface, third data interface, and a fourth data interface, are configured as bidirectional radio interfaces.

16. A method of operating an electrical consumer connected to an electric power system via a circuit breaker, the method comprising:
in order to start up the electrical consumer, transmitting a switch-on command, using a regulation and/or control unit, to the circuit breaker via the data interfaces;
subsequently, closing an electrical breaker gap of the circuit breaker a switch-on unit of the circuit breaker; and
in order to shut down the electrical consumer, transmitting a switch-off command, using the regulation and/or control unit, to the circuit breaker via a first data interface;
subsequently, opening the electrical breaker gap of the circuit breaker using a switch-off unit of the circuit breaker, so as to shut down the electrical consumer.

17. The circuit breaker of claim 2, wherein the semiconductor interrupter arrangement includes an IGBT.

18. The circuit breaker of claim 4, wherein the measuring arrangement is configured to measure an apparent power and/or an effective power.
